(19) United States
(12) Patent Application Publication
(10) Pub. No.: US 2024/0085538 A1
(43) Pub. Date: Mar. 14, 2024

(54) Arbitrary Optical Waveform Generation Utilizing Frequency Discriminators

(71) Applicant: Ivan S. Grudinin, South Pasadena, CA (US)

(72) Inventor: Ivan S. Grudinin, South Pasadena, CA (US)

(21) Appl. No.: 18/518,259

(22) Filed: Nov. 22, 2023

Related U.S. Application Data
(63) Continuation-in-part of application No. 17/302,460, filed on May 3, 2021.
(60) Provisional application No. 62/704,334, filed on May 5, 2020.

(51) Int. Cl. G01S 7/4911; G01S 17/34; H01S 5/0687

(52) U.S. Cl. CPC G01S 7/4911; G01S 17/34; H01S 5/0687

(57) ABSTRACT

A system where a laser having an input that controls the frequency of laser emission, an optical frequency discriminator, and a control system are configured such that the laser frequency can be swept according to a desired function of time. In particular a linear triangular frequency output is achieved which is a repeating sequence of linearly increasing optical frequency and a linearly decreasing optical frequency. The control system relies on a frequency discriminator signal to obtain the information about laser frequency. During generation of repeating swept frequency waveforms the laser frequency remains between the adjacent periodic features of the discriminator optical frequency response. The control system dynamically or iteratively optimizes the laser frequency control signal to maintain the desired laser optical frequency sweep.

This application claims the benefit of U.S. patent application Ser. No. 17/302,460 entitled “Arbitrary Optical Waveform Generation Utilizing Frequency Discriminators” and filed 3 May 2021, and incorporates it herein by reference.

### BACKGROUND

Light detection and ranging (lidar) systems measure distance to a target in an environment by illuminating the target with laser light and measuring reflected light (lidar return). Lidar is useful for remote imaging in real time for autonomous driving, collision avoidance, navigation, 3D scanning, motion capture and the like. Lidar systems can utilize frequency modulated continuous wave (FMCW) laser sources to measure the radial velocity of the target simultaneously with the distance. Such systems are sometimes called FMCW, Doppler or coherent lidar. The modulation of the FMCW laser source is repeated for each measurement, thus FMCW laser sources with high modulation repetition rate support high rate of measurements.

Of particular importance are FMCW laser sources where laser frequency is changing at a constant rate. If one plots the laser frequency as a function of time, the resulting plot will be a straight line. This represents a single linear sweep of the laser frequency. In a practical FMCW lidar a single distance and velocity measurement can be accomplished with a pair of linear frequency sweeps—one with an increasing laser frequency and one with a decreasing laser frequency. Optical frequency excursion during a single sweep can exceed 1 GHz, and the repetition rate of the sweep pair can exceed 100 kHz, resulting in high measurement data rate.

The high data rate capability makes it possible to scan the beam e.g. across an object such as a moving vehicle and to create a 3D image consisting of several recorded points representing the object in the scanned field. FMCW laser radar techniques are described in M.-C. Amann, T. Bosch, M. Lescure, R. Myllyla and M. Rioux, “Laser ranging: a critical review of usual techniques for distance measurement. Opt. Eng. 40, 10-19 (2001), J. Zheng, “Analysis of Optical Frequency-Modulated Continuous-Wave Interference.” Appl. Opt. 43, 4189-4198 (2004), and W. S. Burdic, Radar signal analysis (Prentice-Hall, 1968), Chap. 5. Different lidar types are reviewed and advantages of FMCW are outlined in B. Behroozpour, P. A. M. Sandborn, M. C. Wu and B. E. Boser, “Lidar System Architectures and Circuits,” IEEE Communications Magazine, 55, 135-142 (2017). Also, many aspects of FMCW technique as used with semiconductor lasers (SL) are explained in E. M. Strzelecki, D. A. Cohen, and L. Coldren, “Investigation of tunable single frequency diode lasers for sensor applications. J. Lightwave Technol. 6, 1610-1680 (1988).

Semiconductor lasers (SLs) are attractive for practical applications in FMCW imaging lidar systems because it's possible to electronically control the lasing frequency via the injection current to generate frequency sweeps, including the quickly repeating linear frequency sweeps. Other attractive features of SLs include wide selection of output wavelength, compact size and low cost, narrow spectral line widths of single mode lasers, low power consumption, and ability to convert electric power directly into light. However, precise control of SL frequency has been challenging due to its inherent nonlinearity with respect to injection current. This nonlinearity stems from the SL gain medium dynamics, which becomes especially difficult to control if the direction of frequency tuning is quickly changing and the tuning rate is high. The nonlinearity of diode laser modulation response has been known for a long time. In G. Beheim and K. Fritsch, “Remote displacement measurements using a laser diode.” Electron. Lett. 21, 93-94 (1983) it is shown that a particular SL can only have linear response if its current is swept at under 100 Hz repetition rate.

Prior art methods to linearize SL frequency sweeps and devices producing linear optical frequency sweeps have struggled to operate at high data rate for e.g. imaging applications. For example, an FMCW lidar scanning a scene with a range resolution of under 0.2 m at 200,000 data points per second requires linear optical frequency sweeps of a GHz or more which are repeated every 5 microseconds. For a saw-tooth linear sweep comprising a repeating sequence of linearly increasing optical frequency followed by a linearly decreasing optical frequency a pixel data point can be derived from any pair of adjacent linear sweeps—either an up-down pair or a down-up pair. That is, for a 100 kHz repetition rate of the up-down sweep sequence, the effective data point rate can be twice that rate—200 kHz.

Some prior art methods directly control laser emission frequency by applying distortion to the drive current. Other methods use components external to the laser to measure the waveform resulting from the signal that controls the laser frequency (U.S. Pat. Nos. 7,649,917, 9,559,486). This measurement can be used to improve the linearity of the sweep. The general idea of generating distorted or pre-distorted drive signal can be found in e.g. U.S. Pat. No. 5,436,749.

One method of finding an injection current signal distortion such that the resulting optical frequency sweep in the laser emission is made more linear is described in T. Chen et al., “A Frequency Digital Pre-distortion Compensation Method for FMCW LiDAR System,” paper Th2A.23, Optical Fiber Communication Conference (OFC) 2020. The authors measure frequency response of the semiconductor laser and other system components and compute the distortion of the injection current signal needed to produce the saw-tooth linear optical frequency sweep signal with the laser. This approach was shown to reduce the sweep nonlinearity by a factor of 3 at 10 kHz repetition rate. However, it is not clear if higher sweep repetition rates are supported by the method. Also, this method might be difficult to implement in a compact lidar device unit as it requires sophisticated measurement equipment.

There is a group of methods that rely on optical discriminators to measure laser frequency. In general, the transmission or reflection of a discriminator can be periodic with respect to laser frequency changes. This period can be called a free spectral range (FSR). In all the methods in this group a single sweep of laser frequency covers multiple periods of a discriminator. The methods in this group differ by how they use the measured periodic discriminator signal to control the laser frequency.

Examples of such methods are described in K. Iiyama, L-T. Wang, and K. Hayashi, “Linearizing optical frequency-sweep of a laser diode for FMCW reflectometry,” J. Lightwave Technol. 14, 173-178 (1996), U.S. Pat. Nos. 8,175,126B2, 9,559,486, and 4,893,353A. An optical phase-locked loop (OPLL) can be used for precise control of SL frequency sweeps relying on periodic discriminator output. In OPLL technique, the SL light passes through a discriminator (e.g. an auxiliary interferometer) which generates an electronic beat signal at a frequency proportional to SL frequency tuning rate. This signal is used to stabilize the SL tuning rate by referencing it to a stable oscillator. OPLL-based approaches can provide near ideal linear chirps of up to and above THz span for broadband applications where slow repetition rate is used. However, generation of e.g. approximately GHz sweep span at repetition rates on the order of 100 kHz imposes stringent design requirements on the PLL electronics as shown in a Ph.D. thesis by T. Kim, “Realization of Integrated Coherent LiDAR,” 2019 (https://escholarship.org/uc/item/1d67v62p).

Another method of laser sweep linearization that relies on periodic signals from a discriminator is described in X. Zhang, J. Pouls, and M. C. Wu “Laser frequency sweep linearization by iterative learning pre-distortion for FMCW LiDAR,” Opt. Express 27, 9965-9974 (2019). It relies on a fiber Mach-Zehnder interferometer (MZI) to produce a beat signal at a frequency proportional to the laser tuning rate. A Hilbert transform of the beat signal from the interferometer is used to derive instantaneous laser frequency during the frequency sweep. This instantaneous frequency calculation is then used to iteratively adjust the electronic signal that drives the current through the SL until the frequency sweep as derived from the beat signal measurements matches the desired frequency sweep profile. It may be difficult to use this method to obtain quickly repeating sweeps of moderate bandwidth, e.g. about a GHz frequency excursion at e.g. about 100 kHz repetition rate. The Hilbert transform requires many periods of MZI signal per frequency up-sweep (increasing frequency with time) or down-sweep (decreasing frequency with time) to reliably reconstruct the instantaneous laser frequency during a sweep. A MZI or another discriminator with an FSR (period) much smaller than 1 GHz must have long optical paths, which makes it difficult to integrate in a robust and cost-effective way into compact LiDARs needed for autonomous driving or navigation.

In another group of methods, the laser is tuned over a frequency range that can be smaller than the FSR of a discriminator. Using an optical discriminator such as a Mach Zehnder interferometer (MZI) to generate optical signals to control laser current is mentioned in the US patent application 2020/0025926 A1 paragraphs 0046-0055. However, the application does not provide any disclosure beyond an abstract description and does not claim anything in relation to that description. Using an etalon transmission to implement frequency locking or laser frequency sweeps over a limited set of pre-calibrated values is described in U.S. Pat. No. 7,483,453 B2. However, that approach does not support generation of high repetition rate sweeps or dynamic optimization of the control signals to implement a desired frequency chirp regardless of any thermal or other system non-linearities.

It now becomes evident that there is a need for a simple and low cost FMCW source that can implement very fast laser frequency sweeps with high linearity. Such an FMCW laser source enables compact and robust coherent lidar for multiple applications.

### SUMMARY

The following is a summary of the subject matter presented in this application. It is not intended to limit the scope of the claims.

Described herein are various technologies that pertain to FMCW semiconductor laser sources that generate broadband tunable optical radiation with precise control over its frequency. Highly accurate frequency control is achieved using an opto-electronic system. It includes a feedback loop formed by hardware and an algorithm to control the hardware. Such systems can be made of interconnected and interrelated components configured for optimal and robust generation of frequency sweeps with desired sweep functions, in particular linear repeating saw-tooth sweep. The technologies described also pertain to lidar systems based on such swept laser sources.

The source can include a SL that produces a beam that propagates in free space, or it can include an SL integrated on a chip platform coupled to on-chip waveguides or it can include a laser, a chip platform and a port that can be used to couple the emission from the laser to the chip platform.

The source can also include an optical frequency discriminator. Any optical component or system with a known dependence of some measurable parameter on optical frequency can serve as a discriminator. For example, a Fabry Perot etalon or resonator represented by an optical dielectric or semiconductor window, or a pair of partially reflective mirrors arranged to support optical resonance modes, can be used. In this case the measurable parameter is the optical transmission and optical reflection. The frequency discriminator can also be represented by a waveguide coupled to a waveguide loop or ring or by a Mach-Zehnder interferometer implemented in fiber optics or on a silicon on insulator (SOI) or indium phosphide (InP, III/V) chip platform.

The source can be controlled by a system controller that can include a computing unit or a signal processing system, which controls the components of the source such that it produces the optical signal with a desired frequency sweep. The signal processing can rely on measurements of the signal representing SL power transmitted through an optical frequency discriminator and the signal representing a measure of optical power of the SL. Such measurements can be done with photodetectors, amplifiers, filters, and other supporting electronic components.

Pursuant to various embodiments, an FMCW laser source having a wide frequency range and precise control of the frequency of optical emission can include a semiconductor laser with the injection current input. Providing a current into this input can result in an optical laser output with optical frequency that depends on the injection current in a nonlinear way. A digital signal generator is coupled to control the output of the semiconductor laser by varying the injection current input thereto, with the measurement system including a signal divider receiving the laser output and providing a major laser power output signal and a feedback signal therefrom. The isolator can be included right after the SL to prevent any reflected light from returning to the laser. Another signal divider can be included that receives the feedback signal and provides the power sensing signal and the frequency sensing signal. In this arrangement the power of both signals after the second divider remains proportional to major laser power output signal. An optical discriminator receives the frequency sensing signal from the second beam divider and provides an optical discriminator signal that varies in accordance with the laser output frequency. The optical discriminator signal is converted into electronic discriminator signal by a photodetector and associated electronics. The power sensing signal is received by another photodetector. The electrical signals derived from the detectors that receive the power sensing and the optical discriminator signals are measured and processed in the signal processing system to create the voltage signal. This voltage signal controls the laser injection current via a current source. The current source has a modulation input that can be controlled by the voltage signal to produce laser injection current modulation. The current source can also receive data communication signals from the signal processing system. These signals can instruct the current source to output a predetermined constant injection current bias value added to the modulation current. The algorithm in the signal processing system adjusts the voltage signal until the desired laser frequency sweep is obtained. In cases where laser output power does not depend on the injection current, such as in the case of lasers consisting of a lasing section and a gain section, the power monitoring arrangement may not be required.

Pursuant to various embodiments a lidar system can include a FMCW laser source and a signal divider that provides a local oscillator (LO) signal and a major lidar output signal. The lidar system can include a focusing lens on the LO signal path. The lidar system can also include an optical circulator that passes the major lidar output signal through and deflects the optical lidar return signal into another direction. The device can include a telescope for beam shaping and can include beam steering components and a protective window filter that blocks radiation outside of the SL operating wavelength. The output of the circulator passes through the telescope, beam steering and window components on its way to a remote target. The major lidar output signal illuminates the target, and a portion of this signal is scattered by the target to become the optical lidar return signal. A portion of this return signal then reaches the circulator which now deflects it toward an optional focusing lens. The lidar device can also include a beam splitter which also acts as a beam combiner. It receives the LO signal and splits it in two parts. One part is received by a signal detector and another part is received by another signal detector. The splitter/combiner also receives the lidar return signal and splits it into two parts that reach the two signal detectors. The detectors are arranged in what is known as a balanced detector configuration and provide the electronic lidar return signal. For background on balanced detector configuration see e.g. R. Stierlin, R. Baettig, P. Henchoz, et al. “Excess-noise suppression in a fibre-optic balanced heterodyne detection system.” Opt. Quant. Electron. 18, 445-454 (1986). Some or all the components mentioned here can be replaced with their integrated photonic counterparts if the lidar system and the FMCW source are implemented on a chip platform.

An electronically tunable laser system includes a laser configured to generate a laser output beam having an output beam frequency that is controlled by a control signal. The laser system is designed to generate a desired laser frequency sweep or chirp, such as a saw-tooth linear sweep.

This is accomplished by sweeping the control signal within a sweep range, monitoring frequency variations in the laser output beam, converting these frequency variations into a variation signal using a discriminator, obtaining a current normalized discriminator transmission function based on the variation signal, determining a desired laser frequency modulation function, determining a desired normalized discriminator transmission function based on the desired laser frequency modulation function, and comparing the current normalized discriminator transmission function to the desired normalized discriminator transmission function.

Then if the difference between the current normalized discriminator transmission function and the desired normalized discriminator transmission function (an error signal) exceeds a threshold, the shape of the control signal sweep is revised. This process is repeated until the error signal does not exceed the threshold, though the desired normalized discriminator transmission function and the desired laser frequency modulation function likely remain static and don't need to be determined again.

This method may determine the sweep range by sweeping the laser frequency, determining a maximum and minimum transmission of the discriminator, determining a limited sweep range such that the discriminator transmission function is a single valued function of the control signal, and setting the sweep range according to the limited sweep range.

The discriminator might be, for example, an etalon or a Mach-Zehnder interferometer. The laser can a semiconductor laser. The system might include an isolator to prevent reflected light from returning to the laser. The control signal might be an injection current into the laser, or it could be voltage value within the system that controls the output beam frequency.

The method may include further steps. For example, the power of the laser output beam may be monitored, and the variation signal adjusted to account for power changes. The method may include the step of ensuring constant amplitude and offset of the current laser frequency modulation function. Several variation signals may be combined in some manner, such as averaged, to reduce noise. Several error signals may also be combined, for example by averaging or filtering. A correction may be added to the desired normalized discriminator transmission function.

The above summary is not an extensive overview of the systems and/or methods discussed herein. It represents a simplified overview that provides a basic understanding of some aspects of the systems and/or methods discussed here. It is not intended to identify key/critical elements or to outline the scope of such systems and/or methods. Its only purpose is to provide some concepts in a simple form as an introduction to the more detailed description that is presented later.

### BRIEF DESCRIPTION OF THE DRAWINGS

FIG. 1 illustrates a schematic representation of discrete-optical discriminator examples.

FIG. 2 illustrates a block diagram of an exemplary FMCW laser source.

FIG. 3 illustrates exemplary signals at the beginning of FMCW laser source sweep optimization.

FIG. 4 illustrates a schematic of an exemplary FMCW laser source implemented on a chip platform.

FIGS. 5A-H illustrate a process that controls the FMCW laser source. FIG. 5A shows a process for refining the control. FIG. 5B shows a process for both initializing and refining the control. FIG. 5C, FIG. 5D, FIG. 5E, FIG. 5F, FIG. 5G, and FIG. 5H shows details of steps of FIG. 5B.

FIG. 6 illustrates exemplary optimized signals of FMCW laser source.

FIG. 7 illustrates a schematic of an exemplary lidar system utilizing discrete optical components.

FIG. 8 illustrates a schematic of an exemplary lidar system utilizing integrated and discrete optical components.

FIG. 9 illustrates a schematic of an exemplary signal processing computer system.

### DETAILED DESCRIPTION

Some embodiments provide a FMCW laser source that is simpler than prior art sources or provides faster frequency sweep repetition rates. Some or all embodiments provide a source that is less expensive or easier to make than prior-art sources. In addition to such advantages, the embodiments also provide optical frequency sweep with linear chirp having low deviation from linearity, e.g., less than 1%. Embodiments described here enable low-cost imaging FMCW lidar and chip based FMCW sensors which can be produced in large quantities for the advanced driver assistance systems (ADAS), virtual reality, robotics, autonomous driving and flying, and other applications. These and other benefits of one or more aspects will become apparent from a consideration of the ensuing description and accompanying drawings.

Technologies pertaining to generation of optical beams with frequency swept in a desired way are now described with reference to the drawings. In the following description specific details are set forth to provide a thorough understanding of one or more aspects. It may be evident that such aspects may be practiced without these specific details. In other instances, well-known structures and devices are shown in block diagram form to help describing one or more aspects. Also, functionality that is carried out by certain system components may be performed by multiple components. Similarly, a component may be configured to perform functionality that is carried out by multiple components.

Moreover, the term “or” is intended to mean an inclusive “or” rather than an exclusive “or.” The phrase “A employs X or Y” is intended to mean any of the natural inclusive permutations, unless specified otherwise or clear from context. Moreover, the articles “a” and “an” as used in this specification and claims should generally be construed to mean “one or more” unless specified otherwise or clear from the context.

Here we use the terms “component” and “system” to encompass computer-readable data storage that is configured with computer-executable instructions that cause certain functionality to be performed when executed by a processor. The computer-executable instructions may include a routine, a function, or the like. The terms “component” and “system” are also intended to encompass one or more optical elements that can be configured or coupled together to perform various functionality with respect to an optical signal. It is also to be understood that a component or system may be localized on a single device or distributed across several devices. Further, as used herein, the term “exemplary” is intended to mean “serving as an illustration or example of something.”

In some embodiments, an optical discriminator such as a Fabry-Perot etalon or a fiber-based interferometer can be used to directly obtain information about the instantaneous frequency of a laser. This information can then be used to control the laser bias current to generate linear frequency sweeps suitable for FMCW ranging. The integrated photonics counterparts of such etalons include a waveguide loop resonator, a waveguide interferometer such as a Mach-Zehnder, a resonator such as a whispering galley mode resonator, an atomic transition line of a vapor cell, or any other component with known dependence of some measurable parameter on optical frequency.

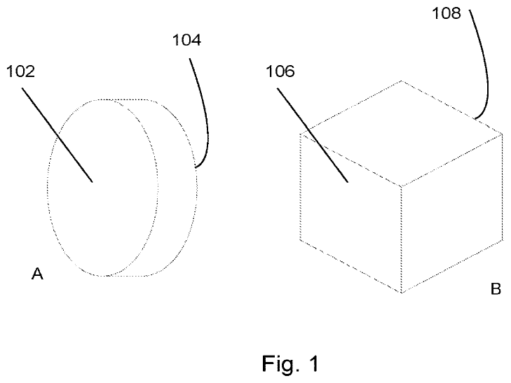

For example, a Fabry-Perot (FP) discriminator was successfully used to generate linear sweeps using the method described here. The FP is a flat silicon window with no coating applied. Referring now to the drawings, FIG. 1-A illustrates a round optical window with plane-parallel flat uncoated surfaces 102 and 104 made of silicon, or an arbitrary shaped e.g., cubic window with similar surfaces 106 and 108 as shown in FIG. 1-B can be used. The window input and output surfaces (102, 104) or partially reflecting mirrors can be planar or non-planar. Planar and non-planar window surfaces or mirrors can form what is known as a FP resonator that functions as a discriminator. The thickness of such FP discriminator can be e.g., between 0.5 and 5 mm.

For clarification, “optical frequency sweep” means a change of optical frequency f according to an arbitrary function F of time t. The function F is called “chirp”, and the sweep can be described as having linear chirp if F(t)=f₀+kt, where f₀ is an initial frequency and k is the constant rate of frequency change. Linear up-chirp is defined as F(t)=f₀+kt, k>0, and a linear down-chirp is defined as F(t)=f₀+kt, k<0. A linear saw-tooth sweep is defined as a sequence of a linear up-chirp and a linear down-chirp that is repeating at some repetition rate.

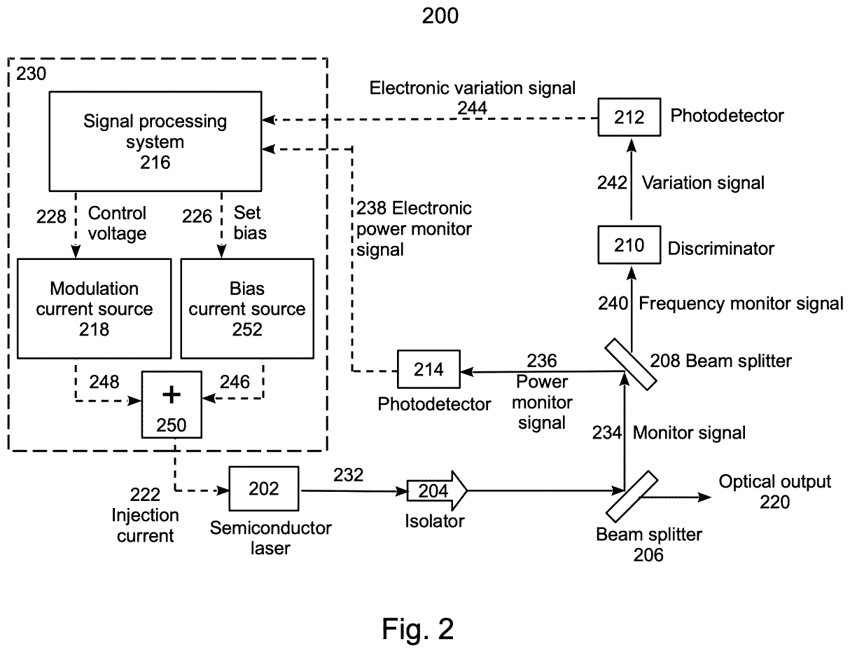

An embodiment of an electronically tunable laser system 200 that can function as an FMCW source is shown in FIG. 2 as a block diagram. The system has a wide frequency range and precise control of the frequency of optical emission. It includes a laser 202 with an injection current input. Laser 202 may be a semiconductor laser. The laser output beam 232 frequency depends on the injection current, generally in a nonlinear way. Those skilled in the art will appreciate that different types of input signals, other than by injection current, could be used to control the frequency of laser output beam 232.

The laser 202 can be distributed feedback (DFB), a distributed Bragg reflector (DBR) or another type of a laser. It can emit laser radiation 232 having any useful wavelength from deep UV to THz, for example a wavelength around 1550 nm or 1310 nm. The laser 202 may incorporate temperature control and sensing elements, and beam focusing optics such as a lens, or it can be a laser on an integrated photonics chip. In this example, the laser output 232 optical beam frequency and power are responsive to the injection current 222 provided by the system controller 230. Injection current 222 is the control signal controlling output beam 232 frequency.

In FIG. 2, system controller 230 is coupled to control the frequency of laser output beam 232 by varying the injection current 222 input thereto. The measurement portion of laser source 200 includes a beam splitter 206 receiving laser output beam 232 and providing a system optical output 220 and a monitor signal 234 therefrom. An isolator 204 can be included right after laser 202 to prevent any reflected light from returning to the laser 202. Some lasers are very sensitive to optical feedback (light scattering and going back into the laser), while other lasers are less/not sensitive and may not benefit from an isolator.

Optionally, another beam splitter 208 receives the monitor signal 234 and provides an optical power monitor signal 236 and an optical frequency monitor signal 240. In this arrangement the power of both signals 236 and 240 remains proportional to system optical output 220 power. Power monitoring is optional because there are lasers that have a gain section working in saturation, so the output power is constant even when the injection current is modified.

An optical discriminator 210 receives the optical frequency monitoring signal 240 from beam splitter 208 and provides an optical frequency variation signal 242 that varies in accordance with laser beam 232 frequency. The optical frequency variation signal 242 is converted into electronic discriminator signal 244 by a photodetector 212 and associated electronics. The optical power monitoring signal 236 is received by another photodetector 214 which generates electronic power monitoring signal 238. Optical discriminator 210 may comprise an etalon or some other device with an output which varies according to laser frequency. These include interferometers, etalons, resonators, atomic transitions in vapor/gas cells, etc. The discriminator 210 can be a Fabry-Perot etalon oriented such that the optical signal 240 arrives at the etalon 210 input surface at about normal incidence. In one embodiment a 12.5 mm diameter, 3 mm thick uncoated flat polished silicon window was used as an etalon. A window can be implemented in a variety of dimensions and shapes, can be cubic or similar, with diameter or cross section from e.g., 0.5 to 25 mm and with thickness e.g., from 0.1 to 10 mm as schematically shown in FIG. 1. A transmission coefficient of a Fabry-Perot etalon is generally a ratio of the optical variation signal 242 power to the frequency monitor signal 240 power. This ratio is a periodic function of laser output beam 232 optical frequency. This dependence of variation signal 242 on frequency is the reason why etalons are examples of broad category of optical discriminators—they can help discriminate one frequency from another.

The electrical signals 238, 244 are measured and processed in signal processing system 216 within system controller 230 and used to generate injection current 222. In this example, signal processing system 216 creates a control voltage signal 228. This voltage signal 228 controls the laser injection current 222 via a modulation current source 218. Current source 218 generates an injection modulation current 248 controlled by the voltage control signal 228 to produce laser injection current modulation.

A bias current source 252 also receives a set bias signal 226 from signal processing system 216. Set bias signal 226 instructs current source 252 to output a predetermined constant injection current bias value 246. The modulation current 248 and bias current 246 are added or subtracted in a current combiner 250, resulting in injection current 222. In practice, modulation current source 218 and bias current source 252 may be a single element. In cases where laser beam 232 output power does not depend on injection current 222, such as in the case of lasers consisting of a lasing section and a gain section, the power monitoring elements 208 and 214 may not be required. In systems without power monitoring, frequency monitor signal 240 may simply comprise monitor signal 234.

In one embodiment of a discriminator 210, the power of variation signal 242 depends on optical frequency of frequency monitoring signal 240. The variation signal 242 is received by a discriminator monitoring photodetector 212. The photodetectors 212 and 214 convert optical signals into electronic signals. The electronic variation signal 244 and the electronic power monitor signal 238 from the photodetectors 212 and 214 may be recorded by signal processing system 216 using analog to digital convertors (ADC, not shown). The system 216 then generates the control voltage 228 through a digital to analog convertor (DAC, not shown), which controls the current source 218. The system 216 can also output digital command set bias 226 to control the bias current source 252.

Detector 212 can be a separate component or can be part of discriminator 210, and the same applies to detector 214 and beam splitter 208. The signal processing system 216, the current sources 218, 252, and the combiner 250 can be represented by physical blocks inside the system controller 230 or can be functional elements of the system controller 230. The system controller 230 can have additional functionality, e.g., controlling the temperature of the laser 202, the discriminator 210, and any other system component. The current sources 218, 250 can be controlled digitally or by a control voltage. The components described above can together be considered an example of an opto-electronic digital feedback loop.

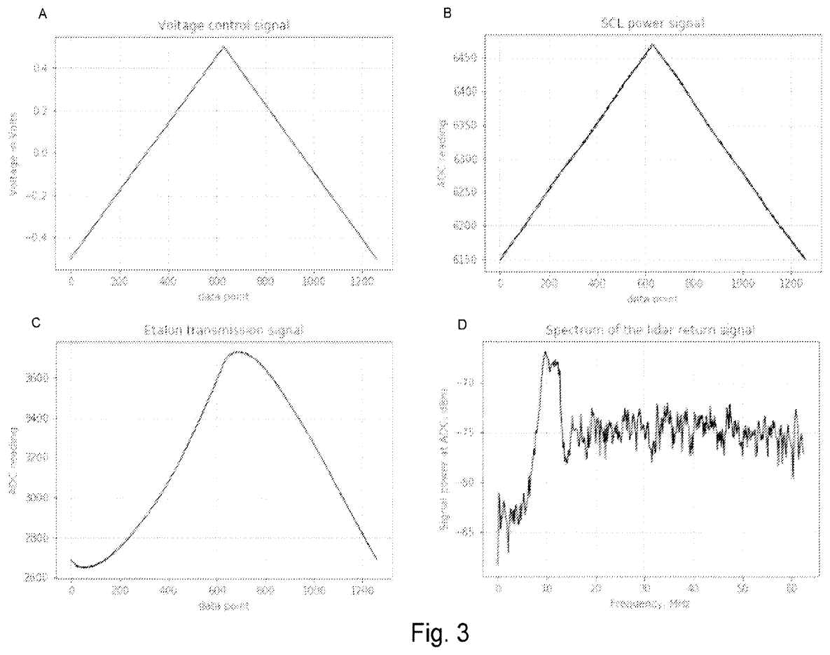

To initiate generation of arbitrary optical frequency sweeps from the SL 202 in this embodiment, the signal processing system 216 creates a control voltage 228 which is a periodic linear saw-tooth-shaped voltage, one period of which is shown in FIG. 3-A. One may say that the initial control voltage 228 has a linear shape since it is a linear function of time. This voltage is applied to the modulation input of the current source 218. The current source 218 generates injection modulation current 248 proportional to control voltage 228. The system 216 can also issue a command to the bias current source 252 to produce a certain amount of injection bias current 246. The bias current 246 is typically much larger than the variation of modulation current 248. For example, a bias current 246 can be 100-200 mA and the variation of the current 248 due to the control voltage signal 228 can be around 5-10 mA.

The combiner 250 produces the injection current 222 which is applied to the current injection input of the SL 202, resulting in the laser output beam 232 that is modulated in power and frequency. This modulation is nonlinear with respect to the applied modulated injection current 222. The power modulation is measured by the power monitoring detector 214 via the power monitor signal 236. The frequency sensing beam 240 is received by the etalon 210 which acts as a frequency discriminator producing a frequency dependent variation signal 242 which is measured by detector 212. Thus, the variation signal 242 is affected by both etalon 210 transmission as a function of optical frequency and by the modulation of optical power of the laser. The purpose of the power measurement by the photodetector 214 is to cancel the effect of power modulation from the signal 244.

In some embodiments, the second beam splitter 208 can be replaced by a circulator that, in addition to passing the feedback signal to the optical discriminator 210, also receives the signal reflected from the discriminator and directs that reflected signal to a power monitoring photodetector 214. The use of the circulator makes it possible to increase measurement precision and to compute the monitor signal power by adding the values of the measurements provided by detectors 214 and 212.

The fraction of optical power transmitted by a non-ideal Fabry-Perot etalon is given by the following FP equation:

P_{transmitted}/P_{incident}=η=(1−p)(1−R)²/4R sin²(2πdfn/c)+(1−R)²+p (1)

where R is a power reflection coefficient of etalon mirrors or surfaces (assumed same for both mirrors for clarity), dis the distance between the reflective surfaces, f is the optical frequency, n is the refractive index of the material filling the space between the reflective surfaces. Etalon material refractive index n depends on optical frequency f, temperature, and pressure unless the space between the reflective surfaces is vacuum with n=1. c=299,792,458 m/s is the speed of light in vacuum. p is the fraction of SL emission that does not resonate within the etalon due to non-ideal mode matching or misalignment. In practice, p can be found from Eq. (1) if R and the minimum value of etalon transmission ηₘᵢₙ are known, using the following p-equation:

p=(ηₘᵢₙ−1)(1−R)²+4Rηₘᵢₙ/4R (2)

Generally speaking, the process of generating an arbitrary waveform (such as frequency sweeps with a desired chirp) includes a feedback loop as follows. Refer to FIG. 2. The frequency of laser beam 232 is swept over a range. This is achieved by sweeping the control signal 228 over a range, which results in input 222 (e.g., injection current) being swept. This initial control signal can be a linear function of time and thus be of a linear shape. A monitor signal 234 is split off to monitor the variations in frequency (and optionally power) of laser beam 232. A discriminator 210 generates an optical variation signal 242 based on the laser beam optical frequency variations. Signal 242 is converted to an electronic variation signal 244 and provided to system controller 230. Electronic variation signal 244 is recorded for corresponding values of control signal 228. This recording is then divided by its maximum value to obtain the current normalized discriminator transmission function. Then a desired normalized discriminator transmission function is obtained from a desired laser frequency modulation. To refine the waveform, the current normalized discriminator transmission function is compared to the desired normalized discriminator transmission function. If the difference between the two exceeds a threshold, the control signal sweep shape is revised. As a result of this feedback loop the signal processing system 216 computes the sequence of values of control signal 228 (its shape) that are required to generate a (known) desired laser frequency modulation function or waveform. The waveform generated might be frequency sweeps with a desired chirp.

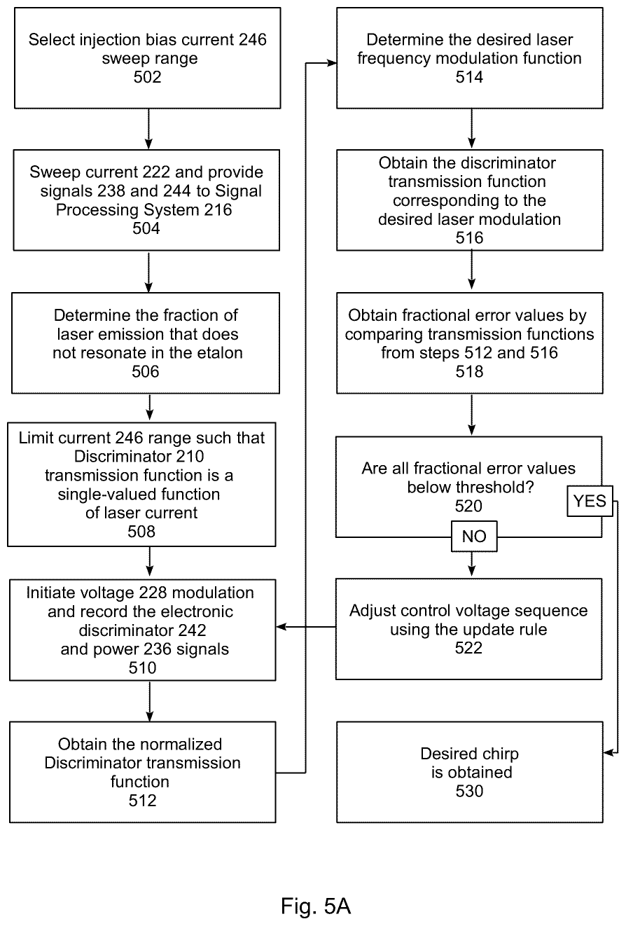

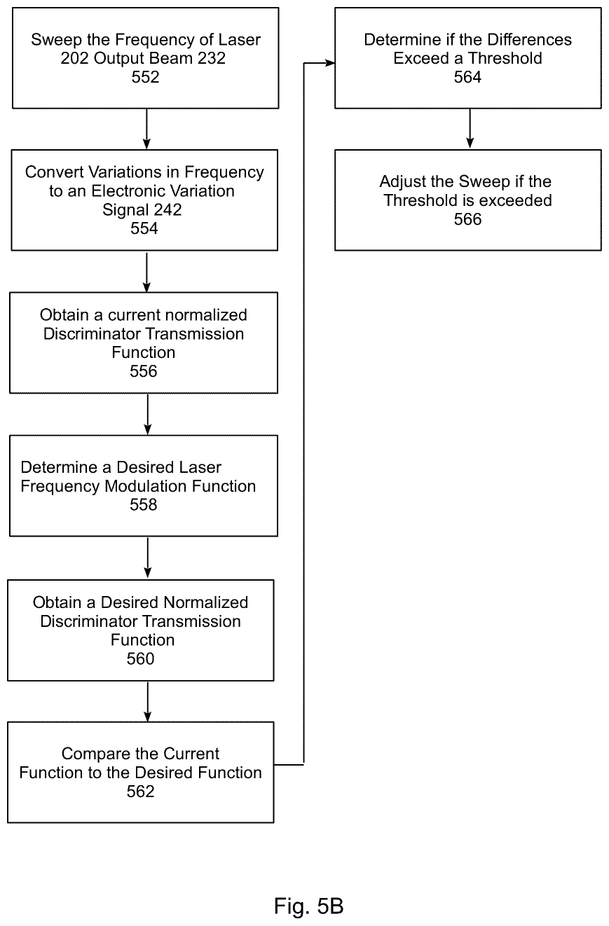

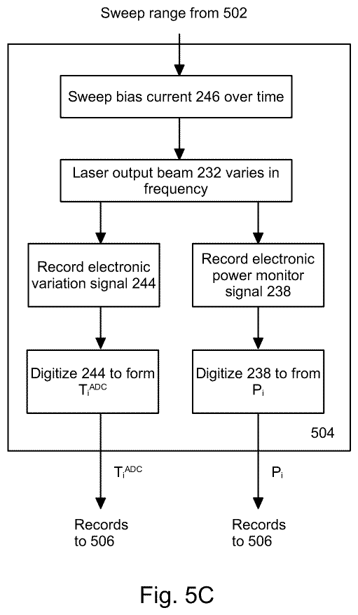

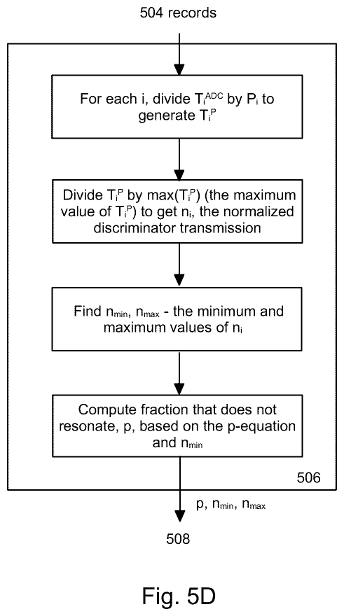

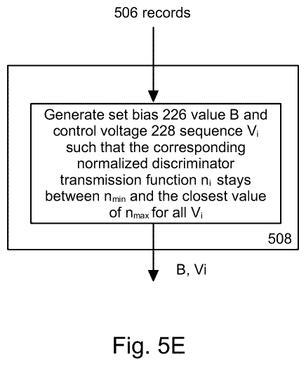

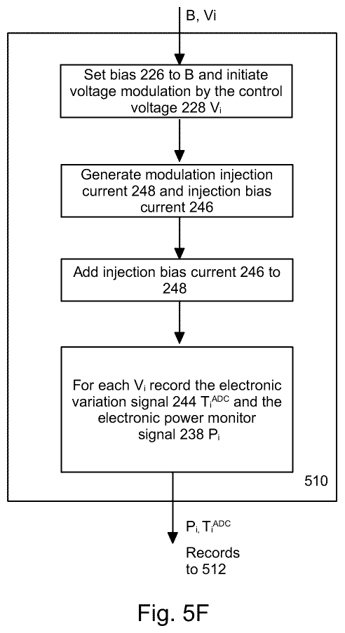

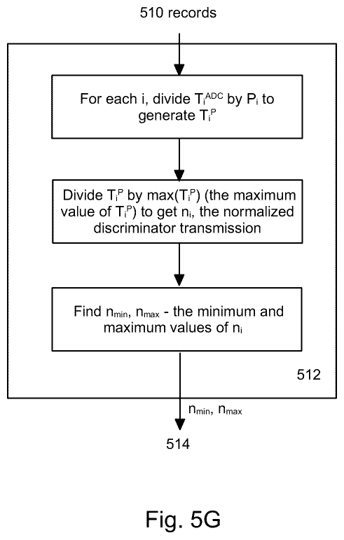

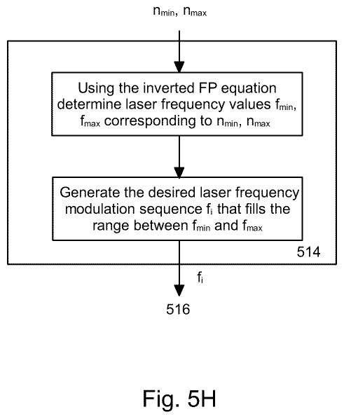

This generalized refining process is shown in FIG. 5B. FIG. 5A, which includes the initializing steps, is described below. In step 552, the frequency of laser 202 output beam 232 is swept over a range (for example by varying control voltage 228 and thus modulation current 248). Variations in the frequency of laser 202 output beam 232 are monitored, for example using frequency monitor signal 240 that is fed into discriminator 210. Electronic variation signal 242 reflects the variation in frequency of the frequency monitor signal 240 because the discriminator 210 (for example an etalon) converts optical frequency variation into optical intensity variation. Thus, step 554 converts variations in laser frequency to an electronic variation signal 242. Step 556 obtains a current normalized discriminator transmission function. See FIG. 5A, step 512 and FIG. 5G. In step 558 a desired laser frequency modulation function is determined. An example of how this is accomplished is shown in FIG. 5A step 514 and FIG. 5H. In step 560 a desired normalized discriminator transmission function is determined. This is also shown in FIG. 5A step 516 and is achieved by substituting the desired laser frequency modulation function into the equation describing the discriminator transmission (e.g., the FP equation). Step 562 compares this desired normalized discriminator transmission function to the normalized discriminator transmission function from step 556. Step 564 determines if differences between the two functions exceed a threshold and step 566 adjusts the shape of the sweep performed if so. See FIG. 5A, steps 518-522 for an example.

FIG. 5A shows an example of this process which includes the initialization process (steps 502-510). The initialization process includes determination of the maximum value of the discriminator 210 transmission function which is needed for normalization and sets the initial sweep range used in step 502 accordingly.

The bias current 246 sweep range, determined by the start and end values of the bias current, is selected in step 502. The range is selected such that the discriminator transmission varies sufficiently during this sweep to include at least one maximum and one adjacent minimum.

In step 504 (see FIG. 5C), the signal processing system 216 generates a sequence of set bias 226 commands to generate a sequence of bias current 246 values that represent a relatively slow linear bias current sweep. The injection modulation current 248 during this sweep is zero or close to zero. The sweep causes laser 202 to change the emission 232 optical frequency while the signal processing system 216 records the electronic variation 244 and power monitor 238 signals at the same time and for values of the bias current. The recording is done by means of an ADC that converts the electronic signals into digital records. The digitized variation signal 244 record is stored in computer memory as Tᵢ^{ADC} along with the digitized power monitor signal 238 record Pᵢ.

In step 506 (and FIG. 5D) the fraction of laser emission that does not resonate in the etalon (p) is determined as follows. The digitized etalon transmission values Tᵢ^{ADC} are divided by the digitized power signal Pᵢ one-by-one (for each i) to compensate for laser power modulation. The resulting compensated record Tᵢ^{P} is further divided by its maximum value max(Tᵢ^{P}) for normalization to unity to obtain ηᵢ. the normalized discriminator transmission function. The minimum value ηₘᵢₙ of the normalized record ηᵢ is substituted into p-equation (Eq. 2) to obtain p.

The FP equation (1) is a periodic function of frequency f=f_{N}+δf, where f_{N}=cN/2dn corresponds to frequency of the etalon transmission peak number N. These periods are also commonly called “fringes”. For a given N, if

0<δf<c/4dn,0>δf>−c/4dn (3)

the etalon transmission is a single-valued function of δf (i.e. it provides only one value of η for each possible δf). In other words, the etalon transmission remains between the N-th peak and the following (0<δf<c/4dn) or the preceding (0>δf>−c/4dn) transmission minimum. This can be achieved at step 508 (and FIG. 5E) by constraining the injection current 222 to a certain range. One finds the set bias 226 value B and the sequence Vᵢ of the control voltage 228 values that ensure the injection current 222 is constrained as described.

Since the etalon function is now single-valued, it is possible to invert it to find δf as a function of η(f):

δf=c/2πdn arcsin \sqrt{(1−R)²(1−η)/4R(η−p).} (4)

The above inverted FP equation reconstructs laser frequency changes δf(t) from a measurement of discriminator transmission η(t). Similar sets of equations describing other examples of discriminators can be derived.

Reconstruction of laser frequency from discriminator transmission can be used in so-called resampling methods for FMCW lidar. The non-linear frequency sweep can effectively be made linear by resampling of the digitized lidar return signal relying on the knowledge of instantaneous frequency from the discriminator. The method would be as follows. Apply linear bias current modulation to the laser. Record the interference signal between the LO signal and the lidar return signal from the remote target on the detector and digitize it by sampling at a constant rate. Record the etalon and power signals Tᵢ^{ADC}, Pᵢ simultaneously with the linear current sweep. Reconstruct δf(t) from those signals and resample the interference signal at a rate which is a function of δf(t) and other parameters. Resampling is a computational operation. The resampled lidar signal will result in a narrow lidar return spectral peak after the Fourier transform.

In step 510 and FIG. 5F, a linear, discrete-valued control voltage 228 sequence is made of an up-chirp Vᵢ=−Vₘ+ki followed by a down-chirp Vᵢ=Vₘ−ki, where iϵ[0, N−1] is the data point index, Vₘ is the modulation amplitude, and k=2 Vₘ/(N−1). These voltages represent the shape of the control voltage signal. The voltages are calculated and produced by the signal processing unit 216 at S values per second. The sequence of up and down voltage sweeps is repeated as long as needed, at a repetition rate of S/2N. This control voltage 228 is received by the modulation current source 218 which converts the control voltage 228 sequence into injection modulation current 248 sequence with some coefficient of conversion a. The combiner 250 adds current 248 to the injection bias current 246 which does not normally change during modulation. The addition produces the injection current 222, for example: I_{SL}=I_{b}+aVᵢ. The combined injection current 222 is generated such that the SL frequency is in the correct range of Eq. 3 (e.g., on the slope of the etalon transmission peak), according to the limits set in step 508. The electronic variation signal 244 and the electronic power monitor signal 238 are recorded into digitized sequences simultaneously with the output of the control voltage 228 sequence.

A laser 202 output beam 232 frequency is a nonlinear and generally not directly known function of current: f₀+δf(t)=Fₘ(I_{b}+Iₘ(t)), where I_{b} is the constant bias offset current and Iₘ(t) is the modulation current to create frequency sweeps. This non-linearity results in the non-linear SL frequency sweep when SL is driven by the linear Vᵢ sweep shown in FIG. 3-A. When such nonlinear SL frequency sweep is used in an FMCW lidar, the spectrum of the electronic lidar return signal is broadened (poor spatial resolution) and has low power (poor sensitivity) as shown in FIG. 3-D. This signal is not generally desirable for the FMCW lidar and the spectrum demonstrates the need to generate the linear SL frequency sweep.

The goal of the algorithm is to find an injection modulation current 248 sequence Iₘ(t)=aVᵢ that results in a desired frequency modulation function δf(t) of the laser output beam 232. Since the desired frequency modulation function is known (e.g., linear sawtooth), the corresponding etalon transmission function ηᵢ⁰ is also known from the FP equation (1). To achieve the desired injection modulation current 248 sequence, one starts with an initial linear control voltage 228 sequence Vᵢ and measures the corresponding etalon transmission function ηᵢ as described in step 510 in the next paragraph. The algorithm then adjusts Vᵢ until the difference between the desired ηᵢ⁰ and measured ηᵢ is below some threshold for all i. Since we constrained the SL injection current 222 to the range where η is a single-valued function of δf(t) (Eq. 3), equality of ηᵢ and ηᵢ⁰ implies equality of Fₘ(I_{b}+I⁰ₘ(t)) and the desired f₀+δf(t).

In some SLs, the change in injection current leads to changes in both optical frequency and output power. For every possible or required value of δf one can measure the SL power variations and normalize (divide) the measured etalon transmission Tᵢ^{ADC} by the measured power values Pᵢ, and by the maximum etalon transmission value max(Tᵢ^{ADC}) determined in the calibration step 506 to directly obtain the values of ηᵢ normalized to 1 as in Eq. (1). An illustration of step 510 is as follows. The linear modulation injection current 248 is proportional to the control voltage 228 sequence shown in FIG. 3-A. The resulting electronic power monitor signal 238 is recorded by the signal processing system 216 as shown in FIG. 3-B. The digitized electronic variation signal 244 is also recorded as shown in FIG. 3-C.

In step 512 the etalon transmission signal (digitized electronic variation signal 244) shown in FIG. 3-C is divided by the recorded power monitor signal 238 and by the calibration value max(Tᵢ^{ADC}) to obtain normalized ηᵢ. The maximum and the minimum values ηₘᵢₙ, ηₘₐₓ of ηᵢ are also found in this step. This is analogous to step 556 in FIG. 5A.

In step 514, from the obtained values of ηₘᵢₙ and ηₘₐₓ and equation (4), one finds the boundary values fₘᵢₙ, fₘₐₓ and all the remaining values in between according to e.g., the desired linear frequency sweep function:

fᵢ=fₘᵢₙ+i·(fₘₐₓ−fₘᵢₙ)/(N−1) (5)

Where iϵ[0, N−1] and Nis the number of data points in each up-chirp or down-chirp. It's worth noting that it is easier to work not with the absolute values off but rather with the values of the argument of the sin function from Eq. 1. This aligns with step 558 in FIG. 5A.

In step 516 (560 in FIG. 5A) the etalon transmission values corresponding to the desired linear optical frequency sweep (5) values fᵢ are now computed according to FP equation (1) as ηᵢ⁰(fᵢ). In step 518 (562) the fractional error values are computed to quantify the deviation of the etalon transmission induced by the injection modulation current 248 sequence from the one corresponding to the desired linear optical frequency sweep:

Eᵢ=(ηᵢ−ηᵢ⁰)/ηᵢ (6)

In step 520 (564) one can now check if all fractional error values Eᵢ are below some preselected threshold value for all i. If they are, the algorithm can be considered complete and finish in step 530. The generation of injection modulation current 248 sequence can continue after that as long as needed. If the fractional error values are not all below the threshold, one can reduce them in step 522 (566) by modifying the control voltage 228 sequence initiated in step 510 (which controls the injection modulation current 248 sequence) according to the following update rule:

Vᵢ=Vᵢ−k(N−1)Eᵢα (7)

where α is an empirically determined parameter that provides optimum convergence of the algorithm. The sign of α must be correct for convergence. After this update the SL will be driven by a nonlinear injection modulation current 248 sequence but the etalon transmission resulting from it is closer to the one which would have resulted if the SL frequency were swept linearly. Thus, the update rule above modifies the shape of the control voltage signal 228. The etalon transmission values ηᵢ resulting from the modified modulation injection current sequence are now recorded again in step 510 and the procedure to adjust Vᵢ in steps 510-522 is repeated until all Eᵢ are sufficiently small for the algorithm to transit to step 530. At that point the desired SL output beam 232 frequency chirp is achieved, and the corresponding control voltage 228 Vᵢ sequence can be stored for later quick start. Before transitioning to step 530, the steps 510-522 can be repeated as long as needed. The update rule above can lead to the drift in the peak and average values of the Vᵢ sequence. An optional calibration step can be included to prevent this drift. First, the minimum and maximum values of Vᵢ are found and the average of those is subtracted from all Vᵢ values. Then all Vᵢ values are multiplied by a constant such that the amplitude of Vᵢ (difference between maximum and minimum values of Vᵢ) is maintained according to a preset level after each iteration of the above update rule.

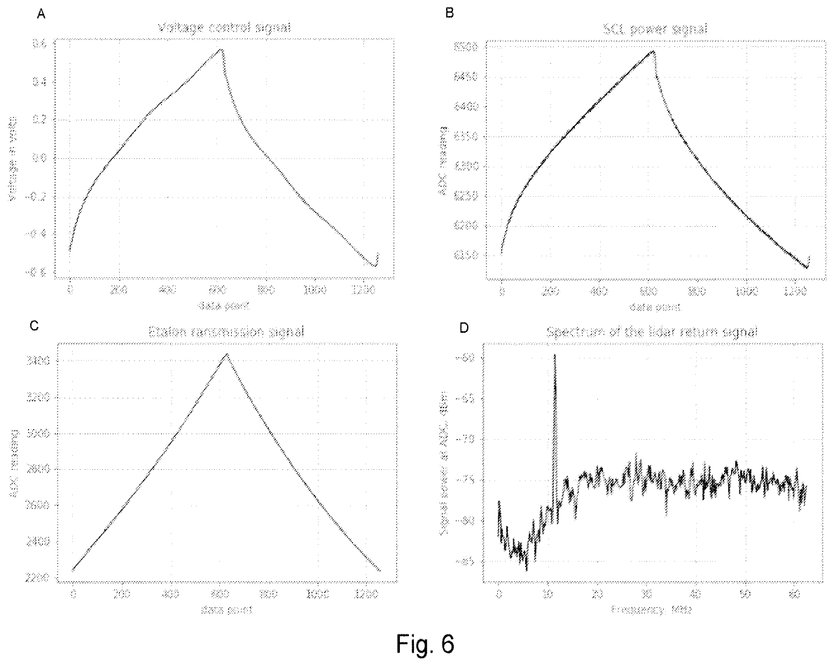

The steps of the algorithm that implements the above descriptions and operates the embodiments are summarized as a flowchart in FIG. 5A. The example control voltage 228 sequence obtained by the algorithm after several updates for a particular hardware embodiment is shown in FIG. 6-A. The corresponding recorded electronic power monitor signal 238 is shown in FIG. 6-B, the recorded electronic variation signal 244 (etalon transmission) is shown in FIG. 6-C. These signals correspond to linearized sweep of the laser output beam 232 optical frequency. This is evidenced by the spectrum of the FMCW lidar return signal which is now more narrow (high spatial and velocity resolution) and of higher power (high sensitivity) as shown in FIG. 6-D. Thus, the above equations and method were verified to generate a linear saw-tooth optical frequency chirp with the described apparatus, which is useful for FMCW lidar.

It is possible that other methods to derive the optimum voltage signal that results in linear frequency sweep can be used other than the iterative approach outlined above. It might be possible to derive the optimum sweep from a few measurements of the SL response to the linear current sweep via the etalon function. Alternatively, a current oscillation at various frequencies or a current step (an abrupt change of current) can be applied to the SL and changes in its emission power and frequency can be measured with the apparatus described here. From these frequency response or step response functions it might be possible to compute the optimum current profile that results in arbitrary desired frequency sweep.

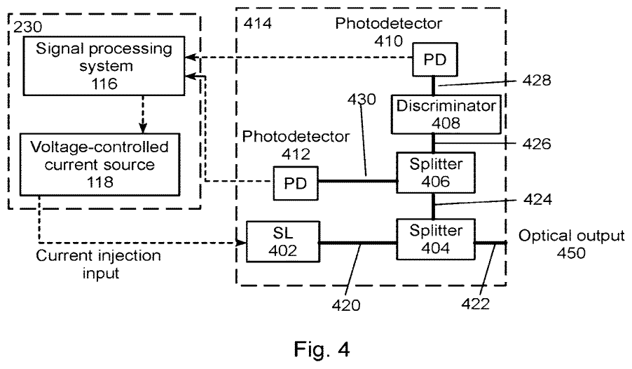

The etalon 210 in FIG. 2 can be replaced with any fiber-based or waveguide-based interferometer such as Mach-Zehnder or other type, which can provide the interference behavior similar to the one of a classical Fabry-Perot etalon. The laser and the detectors can be all integrated on a chip platform, or the standalone laser can be integrated with a chip platform by means of a coupling port. Thus, an embodiment integrated on a chip platform is possible, as schematically illustrated in FIG. 4. Here, the SL 402 can be integrated on a chip platform or be off-chip and coupled to the waveguides of the chip via coupling elements (not shown). The embodiment can include optical waveguides on a chip 420, 422, 424, 426, 428, 430 that physically connect various components on a chip and support an optical mode by which light can be transmitted through such waveguides. The arrows represent electronic signals, and the blocks represent integrated photonic components on a chip. The splitter 404 directs a small portion of the major laser output towards another splitter 406 and provides a major optical output 450. The splitter 406 separates the incoming signal into the power sensing signal carried by waveguide 430 and the frequency sensing signal carried by waveguide 426. The power sensing signal is transmitted by a waveguide 430 to the detector 412, and the frequency sensing signal is transmitted via waveguide 426 to discriminator 408 which can be a waveguide loop resonator or a waveguide interferometer for example. The signal transmitted by the discriminator 408 through the waveguide 428 is measured by the detector 410. The operation of this embodiment is conceptually similar to the operation of the other embodiment shown in FIG. 2.

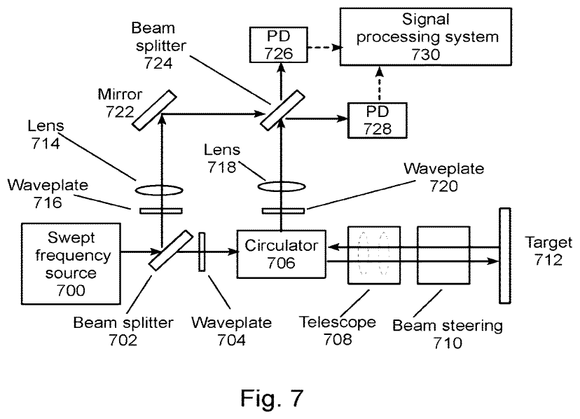

An exemplary FMCW lidar system implemented with free space optics and including an FMCW source embodiment similar to described above is shown as a block diagram in FIG. 7. Such lidar system was designed and built to test the arbitrary waveform generator embodiment described above. It includes the source 700 which provides the major power output which is received by a beam splitter 702. The splitter 702 deflects a portion of the major power output (typically a few percent) to become a local oscillator signal (LO). The system can include a half-wave plate 716 which can rotate the LO signal polarization plane. The system can further include a lens 714 that can be used to focus the LO signal on the detectors 726, 728. The mirror 722 is used to deflect the LO beam towards the beam splitter 724 which can have splitting ratio of about 50%. The system can include a half-wave plate 704 which can be used to control the polarization of the major power output. This may or may not be needed, as this polarization controls how the circulator 706 directs light, e.g., how much of the major power output is passed by it and how much is deflected. Waveplates here are optional. The circulator 706 transmits the major power output towards the telescope 708 which shapes the beam and its wave front. The telescope passes the beam to the beam steering mechanisms 710 and the beam is sent to a remote target 712. The target scatters some of the light back towards the elements 710, 708 and 706. This scattered light becomes the optical lidar return signal as the circulator 706 now deflects this light towards the half-wave plate 720. The plate 720 passes light to lens 720 that focuses the lidar return optical signal onto the photodetectors 726, 728. The beam splitter 724 splits both the LO and the optical lidar return signals into two beams nearly equal in power, so each of the photodetectors 726,728 receives about half of each beam. The split LO and lidar return signals beams are made to overlap on the detectors. These detectors 726, 728 are connected in the balanced detector configuration and they provide the electronic signal to the signal processing system 730 which outputs the electronic lidar return signal.

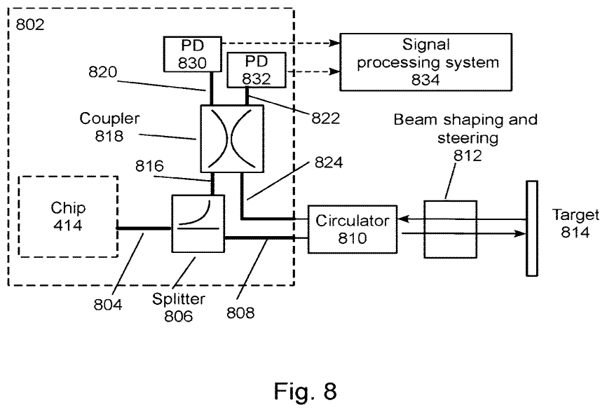

Referring now to FIG. 8, another example of a lidar system is shown based on integrated photonics and free space components. Here, the components depicted on chip 414 of FIG. 4 can be included on a chip 802 along with more components and waveguides to form a coherent transceiver. For example, an FMCW source 414 provides output beam that is transmitted on a chip by a waveguide 804 to a splitter 806 that passes majority of light to waveguide 808 to become major optical output. The amount of light diverted by the splitter 806 from waveguide 804 to waveguide 816 can be e.g., 1-5% of the power carried by the waveguide 804. That light can be passed on to circulator 810 and the transmitted light is shaped and steered by elements 812. A portion of light reflected or scattered by a target 814 becomes the lidar optical return signal as it reaches the circulator 810. The circulator then couples that return signal into waveguide 824 where it travels to reach the coupler 818 that splits light from each of the waveguides 816 and 824 into about equal parts shared by waveguides 820 and 822. Thus, light from waveguide 816 is mixed with light from waveguide 824 and the mixture is equally split between waveguides 820 and 822. Detectors 830 and 832 convert that light into electronic signal which are processed by the signal processing system 834 to create useful FMCW lidar signals.

The processes described herein for controlling, creating, and using a precise broadband optical waveform may be implemented via software and hardware. The signal processing system 216 or control system 230 can incorporate such software, firmware and hardware or other means, or a combination thereof. The signal processing system 216 or control system 230 can be part of a more general combination of software and hardware with additional functions. The examples of computing hardware components include a field-programmable gate array (FPGA) chip, an application specific integrated circuit (ASIC) chip, a central processing unit (CPU), analog to digital converters (ADC), digital to analog converter (DAC), a digital signal processor (DSP). A CPU can be a separate chip, be part of another chip or be implemented in an FPGA fabric. Such components can be used to record, process, and produce electronic signals for the operation of embodiments of FMCW sources or lidar systems. Such example hardware for performing the described functions is detailed below.

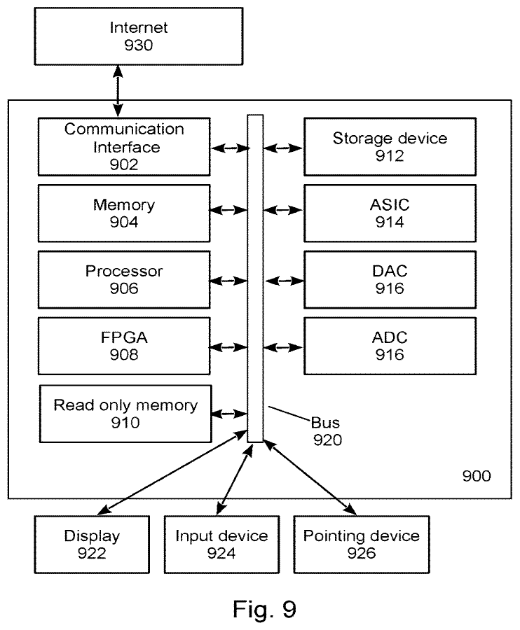

FIG. 9 illustrates computer system upon which an embodiment can be implemented. Computer system 900 includes a communication mechanism such as a bus 920 for passing information between other internal and external components of the computer system 900. Information (also called data) is represented as a physical expression of a measurable phenomenon, typically electric voltages, but including, in other embodiments, such phenomena as magnetic, electromagnetic, pressure, chemical, biological, molecular, atomic, sub-atomic and quantum interactions. For example, a zero and non-zero electric voltage, or south or north magnetic poles, represent two states (0, 1) of a binary digit (bit). Other phenomena can represent digits of a higher base. A superposition of multiple simultaneous quantum states before measurement represents a quantum bit (qubit). A sequence of one or more digits constitutes digital data that is used to represent a number or code for a character. In some embodiments, information called analog data is represented by a near continuum of measurable values within a particular range. A bus 920 includes one or more parallel conductors of information so that information is transferred quickly among devices coupled to the bus 920. One or more processors 906 for processing information are coupled with the bus 920.

A processor 1 A processor 906 performs a set of operations on information. The set of operations include bringing information in from the bus 920 and placing information on the bus 920. The set of operations also typically include comparing two or more units of information, shifting positions of units of information, and combining two or more units of information, such as by addition or multiplication or logical operations like OR, exclusive OR (XOR), and AND. Each operation of the set of operations that can be performed by the processor is represented to the processor by information called instructions, such as an operation code of one or more digits. A sequence of operations to be executed by the processor 906, such as a sequence of operation codes, constitute processor instructions, also called computer system instructions or, simply, computer instructions. Processors may be implemented as mechanical, electrical, magnetic, optical, chemical or quantum components, among others, alone or in combination.

Computer system 900 also includes a memory 904 coupled to bus 920. The memory 904, such as a random-access memory (RAM) or other dynamic storage device, stores information including processor instructions. Dynamic memory allows information stored therein to be changed by the computer system 900. RAM 904 allows a unit of information stored at a location called a memory address to be stored and retrieved independently of information at neighboring addresses. The memory 904 is also used by the processor 906 to store temporary values during execution of processor instructions. The computer system 900 also includes a read only memory (ROM) 910 or other static storage device coupled to the bus 920 for storing static information, including instructions, that is not changed by the computer system 900. Some memory is composed of volatile storage that loses the information stored thereon when power is lost. Also coupled to bus 920 is a non-volatile (persistent) storage device 912, Such as a magnetic disk, optical disk or flash card, for storing information, including instructions, that persists even when the computer system 900 is turned off or otherwise loses power.

Information, including instructions, is provided to the bus 920 for use by the processor from an external input device 924, Such as a keyboard containing alphanumeric keys operated by a human user, or a sensor. A sensor detects conditions in its vicinity and transforms those detections into physical expression compatible with the measurable phenomenon used to represent information in computer system 900. Other external devices coupled to bus 920, used primarily for interacting with humans, include a display device 922, such as a liquid crystal display (LCD), a light emitting diode (LED) display or plasma screen or printer for presenting text or images, and a pointing device 926. Such as a mouse or a trackball or cursor direction keys, or motion sensor, for controlling a position of a small cursor image presented on the display 922 and issuing commands associated with graphical elements presented on the display 922. In some embodiments, for example, in embodiments in which the computer system 900 performs all functions automatically without human input, one or more of external input device 924, display device 922 and pointing device 926 is omitted.

In the illustrated embodiment, special purpose hardware, such as an application specific integrated circuit (ASIC) 914, is coupled to bus 920. The special purpose hard-ware is configured to perform operations not performed by processor 906 quickly enough for special purposes. Examples of application specific ICs include graphics accelerator cards for generating images for display 922, cryptographic boards for encrypting and decrypting messages sent over a network, speech recognition, and interfaces to special external devices, such as robotic arms and medical scanning equipment that repeatedly perform some complex sequence of operations that are more efficiently implemented in hardware.

Computer system 900 also includes one or more instances of a communications interface 902 coupled to bus 920. Communication interface 902 provides a one-way or two-way communication coupling to a variety of external devices that operate with their own processors, such as printers, scanners, and external disks. In general, the coupling is with a network link that is connected to a local or global network (internet 930) to which a variety of external devices with their own processors are connected. For example, communication interface 902 may be a parallel port or a serial port or a universal serial bus (USB) port on a personal computer. In some embodiments, communications interface 902 is an integrated services digital network (ISDN) card or a digital subscriber line (DSL) card or a telephone modem that provides an information communication connection to a corresponding type of telephone line. In some embodiments, a communication interface 902 is a cable modem that converts signals on bus 920 into signals for a communication connection over a electric cable or into optical signals for a communication connection over a fiber optic cable. As another example, communications interface 902 may be a local area network (LAN) card to provide a data communication connection to a compatible network, such as ethernet or internet 930. Wireless links may also be implemented. For wireless links, the communications interface 902 sends or receives or both sends and receives electrical, acoustic or electromagnetic signals, including infrared and optical signals, which carry information streams, such as digital data. For example, in wireless handheld devices, such as mobile telephones like cell phones, the communications interface 902 includes a radio band electromagnetic transmitter and receiver called a radio transceiver.

The term computer-readable medium is used herein to refer to any medium that participates in providing information to processor 906, including instructions for execution. Such a medium may take many forms, including, but not limited to, non-volatile media, volatile media and transmission media. Common forms of computer-readable media include, for example, a floppy disk, a flexible disk, a hard disk, a magnetic tape, or any other magnetic medium, a compact disk ROM (CD-ROM), a digital video disk (DVD) or any other optical medium, punch cards, paper tape, or any other physical medium with patterns of holes, a RAM, a programmable ROM (PROM), an erasable PROM (EPROM), a FLASH-EPROM, or any other memory chip or cartridge, a transmission medium such as a cable or carrier wave, or any other medium from which a computer can read.

Logic encoded in one or more tangible media includes one or both of processor instructions on a computer-readable storage media and special purpose hardware, Such as ASIC 914. A field programmable gate array (FPGA) 908 is a set of connections (gates) on a chip that can be programmed to form various complex connections and thus implement arbitrary digital circuits from simple ones to complex one such as ASIC or a CPU. The FPGA 908 can read its configuration from a computer readable media or from a storage device 912 or from a communication interface 902 or from ROM 910.

Analog to digital converters (ADC) and digital to analog converters (DAC) can be part of some other chips or separate chips. The ADC converts the voltages present at its input into digital representation such as data that can be passed to other components via bus 920 or through direct connections to some devices such as ASICs or FPGA. Similarly, the DAC 916 implements conversion of digital representation of voltages into physical voltages on its output lines.

At least some embodiments described here are related to the use of computer system 900 for implementing some or all of the techniques described herein. According to one embodiment of the invention, those techniques are performed by computer system 900 in response to processor 906 executing one or more sequences of one or more processor instructions contained in memory 904. Such instructions, also called computer instructions, software and program code, may be read into memory 904 from another computer-readable medium such as storage device 912 or a communication device 902. Execution of the sequences of instructions contained in memory 904 causes processor 906 to perform one or more of the method steps described herein. In alternative embodiments, hardware, such as ASIC 914 or FPGA 908 may be used in place of or in combination with software to implement the embodiments of an FMCW laser source. Thus, embodiments of the are not limited to any specific combination of hardware and software, unless otherwise explicitly stated herein.

The high sweep rate FMCW sources described here have applications in FMCW systems wherein precise and fast control of optical frequency is necessary. In particular, FMCW-based lidar for real-time high-resolution imaging will benefit from the high rate of sweep repetition. The sweep amplitude is also of practical importance because the range resolution ΔZ of an FMCW range measurement is ultimately determined by the total frequency excursion B of the optical source during each sweep, ΔZ=c/2B, where c is the speed of light. The resolution here is the ability of an FMCW system to identify two close but distinct targets separated by ΔZ. The systems and methods described here provide a simple and manufacture-friendly way to build FMCW lidar for automotive, drone and other applications. It's likely that simplicity of embodiments will lead to cost advantage. A lower cost lidar with technical specifications sufficient for any application will be desirable in the market.

In Summary, techniques to produce quickly repeating broadband arbitrary and linear frequency sweeps with semiconductor laser diodes are disclosed herein. At least one embodiment of a laser system generates accurate and broadband frequency sweeps using laser injection current signal shaping relying upon an optical etalon as a frequency discriminator. Periodic frequency sweeps of about 1 GHz of optical frequency excursion in about 5 microseconds with deviation from linearity of less than 1% are achieved. This enabled new imaging lidar architecture for automotive and other applications.

The specifics of the above descriptions should not be construed as limitations on the scope, but rather an exemplification of one [or several] embodiment(s) thereof. Many other variations are possible. For example, an optical waveform generator utilizing a non-semiconductor laser such as a laser with solid, crystalline, gaseous or liquid gain medium. A generator can be based on a non-silicon photonics chip such an InP chip or other III/V semiconductor. A generator can be implemented without an isolator or a power measuring photodetector. A signal processing system can be integrated on the same chip platform as the laser and other components, or on a separate chip. A voltage-controlled current source can be a separate component or can be integrated with the signal processing system as its part within the system controller. The described method can be used regardless of any laser tuning mechanism.

What has been described above includes examples of one or more embodiments. It is, of course, not possible to describe every conceivable modification and alteration of the above devices or methodologies for purposes of describing the aforementioned aspects, but one of ordinary skill in the art can recognize that many further modifications and permutations of various aspects are possible. Accordingly, the described aspects are intended to embrace all such alterations, modifications, and variations that fall within the scope of the appended claims. Furthermore, to the extent that the term “includes” is used in either the details description or the claims, such term is intended to be inclusive in a manner similar to the term “comprising” as “comprising” is interpreted when employed as a transitional word in a claim.

What is claimed is:

1. In an electronically tunable laser system having a laser configured to generate a laser output beam having an output beam frequency that is controlled by a control signal, a method comprising the steps of:
(a) sweeping the control signal within a sweep range;
(b) monitoring frequency variations of the laser output beam;
(c) converting frequency variations of the laser output beam into a variation signal using a discriminator;
(d) obtaining a current normalized discriminator transmission function based on the variation signal;
(e) determining a desired laser frequency modulation function;
(f) determining a desired normalized discriminator transmission function based on the desired laser frequency modulation function;
(g) comparing the current normalized discriminator transmission function to the desired normalized discriminator transmission function;
(h) revising a shape of the control signal sweep if a difference between the current normalized discriminator transmission function and the desired normalized discriminator transmission function exceeds a threshold, and
(i) repeating steps (a) through (d), (g), and (h) until the difference between the current normalized discriminator transmission function and the desired normalized discriminator transmission function does not exceed the threshold.

2. The method of claim 1, further including the step of determining the sweep range before step (a) by:
sweeping laser frequency;
determining a maximum and minimum transmission of the discriminator;
determining a limited sweep range such that a discriminator transmission function is a single valued function of the control signal; and
setting the sweep range in step (a) according to the limited sweep range.

3. The method of claim 2 further including the step of determining a fraction of laser emission that does not resonate within the discriminator.

4. The method of claim 2 wherein the discriminator is an etalon.

5. The method of claim 2 further including the steps of monitoring power of the laser output beam and adjusting the variation signal to account for changes in the power of the laser output beam.

6. The method of claim 2 wherein the control signal is an injection current into the laser.

7. The method of claim 2 wherein the desired laser frequency modulation function is a linear saw-tooth sweep.

8. The method of claim 1 wherein the discriminator is an etalon.

9. The method of claim 1 wherein the laser is a semiconductor laser.

10. The method of claim 1 further including the steps of monitoring power of the laser output beam and adjusting the variation signal to account for changes in the power of the laser output beam.

11. The method of claim 1 wherein the control signal is an injection current into the laser.

12. The method of claim 1 further including the step of preventing reflected light from returning to the laser using an isolator.

13. The method of claim 1 wherein the discriminator is a Mach-Zehnder interferometer.

14. The method of claim 1 wherein the desired laser frequency modulation function is a linear saw-tooth sweep.

15. The method of claim 1 further including the step of ensuring constant amplitude and offset of the current laser frequency modulation function.

16. The method of claim 1 further including the step (between step (c) and step (d)) of averaging several variation signals in order to reduce noise.

17. The method of claim 1 wherein the difference between the current normalized discriminator transmission function and the desired normalized discriminator transmission function is an error signal, and further including the step of combining several error signals.

18. The method of claim 1 further including the step of adding a correction to the desired normalized discriminator transmission function.

19. The method of claim 1 wherein signals and functions are represented by corresponding sequences of numbers in computer memory.

20. The method of claim 1 wherein the control signal is a voltage that controls the output beam frequency.
